(19) United States
(12) Patent Application Publication
(10) Pub. No.: US 2011/0215450 A1
(43) Pub. Date: Sep. 8, 2011

(54) INTEGRATED CIRCUIT PACKAGING SYSTEM WITH ENCAPSULATION AND METHOD OF MANUFACTURE THEREOF

(76) Inventors: HeeJo Chi, Ichon-si (KR); NamJu Cho, Uiwang-si (KR); HanGil Shin, Seongnam-si (KR)

(21) Appl. No.: 12/718,939

(22) Filed: Mar. 5, 2010

(51) Int. Cl. H01L 23/552; H01L 21/60; H01L 21/56; H01L 23/48

(52) U.S. Cl. 257/660; 438/124; 438/122; 438/126; 257/E23.114; 257/E21.502; 257/E21.506; 257/E23.01

(57) ABSTRACT

A method of manufacture of an integrated circuit packaging system includes: forming a carrier having a cavity and a carrier top side adjacent to the cavity; mounting an integrated circuit in the cavity; forming an encapsulation surrounding the integrated circuit; and attaching a conductive channel to the carrier top side, the conductive channel over the encapsulation.

### TECHNICAL FIELD

The present invention relates generally to an integrated circuit packaging system, and more particularly to a system for an integrated circuit packaging system with encapsulation.

### BACKGROUND ART

Semiconductor package structures continue to become thinner and ever more miniaturized. This results in increased component density in semiconductor packages and decreased sizes of the IC products in which the packages are used. These developmental trends are in response to continually increasing demands on electronic apparatus designers and manufacturers for ever-reduced sizes, thicknesses, and costs, along with continuously improving performance.

These increasing demands for miniaturization are particularly noteworthy, for example, in portable information and communication devices such as cellular phones, hands-free cellular phone headsets, personal data assistants (“PDA's”), camcorders, notebook computers, and so forth. All of these devices continue to be made smaller and thinner to improve their portability. Accordingly, large-scale IC (“LSI”) packages that are incorporated into these devices are required to be made smaller and thinner. The package configurations that house and protect LSI require them to be made smaller and thinner as well.

As the integrated circuit technology advances, more circuit cells can be fabricated in a similar die area so that substantially increased functionality can be accomplished on a given integrated circuit die. The added functionality and increase in the number of circuits generally involves a larger amount of power dissipation. The increased heat in the package can significantly reduce the life of the integrated circuits in the package.

Thus, a need still remains for an integrated circuit packaging system providing integration and thermal efficiency. In view of the ever-increasing need to increase density of integrated circuits and particularly portable electronic products, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: forming a carrier having a cavity and a carrier top side adjacent to the cavity; mounting an integrated circuit in the cavity; forming an encapsulation surrounding the integrated circuit; and attaching a conductive channel to the carrier top side, the conductive channel over the encapsulation.

The present invention provides an integrated circuit packaging system, including: a carrier having a cavity and a carrier top side adjacent to the cavity; an integrated circuit in the cavity; an encapsulation surrounding the integrated circuit; and a conductive channel attached to the carrier top side, the conductive channel over the encapsulation.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit packaging system along a section line 1-1 of FIG. 2 in a first embodiment of the present invention.

FIG. 2 is a top view of the integrated circuit packaging system.

FIG. 3 is a cross-sectional view of a portion of the integrated circuit packaging system along the section line 1-1 of FIG. 2 in a forming phase of the carrier.

FIG. 4 is a cross-sectional view of the structure of FIG. 3 in a mounting phase of the integrated circuit.

FIG. 5 is a cross-sectional view of the structure of FIG. 4 in a molding phase of the encapsulation.

FIG. 6 is a cross-sectional view of the structure of FIG. 5 in a forming phase of a first via.

FIG. 7 is a cross-sectional view of the structure of FIG. 6 in a forming phase of a first conductive layer.

FIG. 8 is a cross-sectional view of the structure of FIG. 7 in a forming phase of the first inner conductive channel.

FIG. 9 is a cross-sectional view of the structure of FIG. 8 in a forming phase of a first insulation layer.

FIG. 10 is a cross-sectional view of the structure of FIG. 9 in a forming phase of a second via and a peripheral via.

FIG. 11 is a cross-sectional view of the structure of FIG. 10 in a forming phase of a second conductive layer.

FIG. 12 is a cross-sectional view of the structure of FIG. 11 in a forming phase of the second inner conductive channel, the first outer conductive channel, and the second outer conductive channel.

FIG. 13 is a cross-sectional view of the structure of FIG. 12 in a forming phase of a second insulation layer.

FIG. 14 is a cross-sectional view of the structure of FIG. 13 in a forming phase of an opening.

FIG. 15 is a cross-sectional view of the structure of FIG. 14 in a singulation phase of the integrated circuit packaging system.

FIG. 16 is a cross-sectional view as exemplified by the top view of FIG. 2 of an integrated circuit packaging system in a second embodiment of the present invention.

FIG. 17 is a cross-sectional view as exemplified by the top view of FIG. 2 of an integrated circuit packaging system in a third embodiment of the present invention.

FIG. 18 is a cross-sectional view as exemplified by the top view of FIG. 2 of an integrated circuit packaging system in a fourth embodiment of the present invention.

FIG. 19 is a flow chart of a method of manufacture of an integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” means that there is direct contact between elements. The term “directly on” means that there is direct contact between one element and another element without an intervening element.

The term “active side” refers to a side of a die, a module, a package, or an electronic structure having active circuitry fabricated thereon or having elements for connection to the active circuitry within the die, the module, the package, or the electronic structure. The term “processing” as used herein includes deposition of material or photoresist, patterning, exposure, development, etching, cleaning, and/or removal of the material or photoresist as required in forming a described structure.

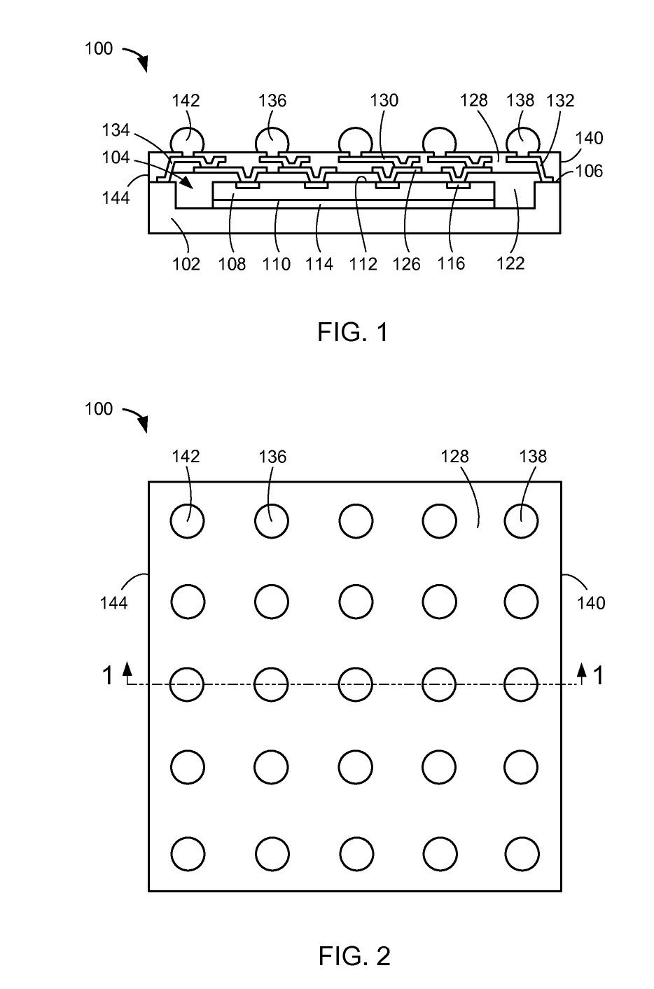

Referring now to FIG. 1, therein is shown a cross-sectional view of an integrated circuit packaging system 100 along a section line 1-1 of FIG. 2 in a first embodiment of the present invention. The integrated circuit packaging system 100 can represent a configuration or application of a packaging system, which can include a Wafer Level Chip Scale Package (WLCSP).

The integrated circuit packaging system 100 can include a carrier 102, such as a heat spreader, an electromagnetic interference (EMI) shield, or a substrate. The carrier 102 can include a cavity 104 and a carrier top side 106 outside and adjacent to the cavity 104.

The integrated circuit packaging system 100 can include an integrated circuit 108, such as a chip, a bare chip, a die, or a semiconductor device. The integrated circuit 108 can include an inactive side 110 and an active side 112 opposite or over the inactive side 110. The active side 112 having circuitry fabricated thereon.

The integrated circuit 108 can be placed or mounted in the cavity 104 or over the carrier 102. The inactive side 110 can be attached to the carrier 102 with an attach layer 114, such as a thermally conductive adhesive, a die attach adhesive, a film, or an epoxy. The attach layer 114 can be attached on the carrier 102. The attach layer 114 can allow transfer or conduct heat away from the integrated circuit 108 to the carrier 102. The integrated circuit 108 can include a bond pad 116. The bond pad 116 can be formed on the active side 112.

The integrated circuit packaging system 100 can include an encapsulation 122, such as a cover including an encapsulant, an epoxy molding compound, or a molding material. The encapsulation 122 can be partially formed over or on the carrier 102, the integrated circuit 108, or the attach layer 114.

The encapsulation 122 can be formed over or in the cavity 104. The encapsulation 122 can be partially formed over or on the carrier top side 106. The integrated circuit 108 can be surrounded by the encapsulation 122.

The integrated circuit packaging system 100 can include a first inner conductive channel 126, such as a patterned routing layer, a redistribution layer (RDL), a build-up layer, a trace, or a wire, formed over or on the encapsulation 122 or the bond pad 116. The first inner conductive channel 126 can conduct or carry electrical signals. The first inner conductive channel 126 can be electrically connected to the bond pad 116.

The integrated circuit packaging system 100 can include an insulation layer 128, such as a dielectric, an epoxy, a glass, a resin, an organic or inorganic material, a plastic or ceramic material, or a thermoplastic material. The insulation layer 128 can be over the carrier 102 covering the encapsulation 122 or the first inner conductive channel 126.

The integrated circuit packaging system 100 can include a second inner conductive channel 130, such as a patterned routing layer, a redistribution layer (RDL), a build-up layer, a trace, or a wire, formed over or on the insulation layer 128 or the first inner conductive channel 126. The second inner conductive channel 130 can conduct or carry electrical signals. The second inner conductive channel 130 can be electrically connected to the first inner conductive channel 126.

The integrated circuit packaging system 100 can include a first outer conductive channel 132, such as a patterned routing layer, a redistribution layer (RDL), a build-up layer, a trace, or a wire, partially formed over or on the carrier 102, the encapsulation 122, or the insulation layer 128. The first outer conductive channel 132 can be adjacent to the second inner conductive channel 130.

The first outer conductive channel 132 can conduct or carry electrical signals. The first outer conductive channel 132 can be connected to the carrier top side 106.

The integrated circuit packaging system 100 can include a second outer conductive channel 134, such as a patterned routing layer, a redistribution layer (RDL), a build-up layer, a trace, or a wire, partially formed over or on the carrier 102, the encapsulation 122, or the first inner conductive channel 126. The second outer conductive channel 134 can be adjacent to another of the second inner conductive channel 130.

The second outer conductive channel 134 can conduct or carry electrical signals. The second outer conductive channel 134 can be electrically connected to the carrier top side 106 or the first inner conductive channel 126.

The insulation layer 128 can be over or on the carrier 102 covering the second inner conductive channel 130, the first outer conductive channel 132, or the second outer conductive channel 134.

For illustrative purposes, the insulation layer 128 is shown as a single integral structure, although the insulation layer 128 can be formed with a number of insulation layers that can be formed over or on one another. The insulation layers can be formed with a common material.

The integrated circuit packaging system 100 can include an inner interconnect 136, such as a bump, a ball, a post, a pillar, or a connector. For example, the inner interconnect 136 can be formed with solder, a metallic material, an alloy, or a conductive material.

The inner interconnect 136 can be formed over or on the second inner conductive channel 130 and optionally partially over the insulation layer 128. The inner interconnect 136 can be connected to the second inner conductive channel 130.

The integrated circuit packaging system 100 can include a first outer interconnect 138, such as a bump, a ball, a post, a pillar, or a connector. For example, the first outer interconnect 138 can be formed with solder, a metallic material, an alloy, or a conductive material.

The first outer interconnect 138 can be formed over or on the first outer conductive channel 132 or optionally partially over the insulation layer 128. The first outer interconnect 138 can be adjacent to the inner interconnect 136. The first outer interconnect 138 can be connected to the first outer conductive channel 132.

The first outer conductive channel 132 can electrically connect or attach to the carrier top side 106 and the first outer interconnect 138. The first outer conductive channel 132 or the first outer interconnect 138 can be formed adjacent to or near a first external non-horizontal side 140 of the insulation layer 128. The first external non-horizontal side 140 can be coplanar with an external surface of the carrier 102.

The integrated circuit packaging system 100 can include a second outer interconnect 142, such as a bump, a ball, a post, a pillar, or a connector. For example, the second outer interconnect 142 can be formed with solder, a metallic material, an alloy, or a conductive material.

The second outer interconnect 142 can be formed over or on the second outer conductive channel 134 and optionally partially over the insulation layer 128. The second outer interconnect 142 can be adjacent to another of the inner interconnect 136. The second outer interconnect 142 can be connected to the second outer conductive channel 134.

The second outer conductive channel 134 can electrically connect or attach to the carrier top side 106 and the second outer interconnect 142. The second outer conductive channel 134 or the second outer interconnect 142 can be formed adjacent to or near a second external non-horizontal side 144 of the insulation layer 128.

The second external non-horizontal side 144 can be coplanar with another external surface of the carrier 102. The second external non-horizontal side 144 can be opposite the first external non-horizontal side 140.

The first outer interconnect 138 or the second outer interconnect 142 can be connected to ground, an external ground potential, or an electrical reference point that is external to the integrated circuit packaging system 100. The first outer conductive channel 132 connected to the first outer interconnect 138 or the second outer conductive channel 134 connected to the second outer interconnect 142 can provide a grounding path for the carrier 102 to function as an electromagnetic interference (EMI) shield.

For illustrative purposes, the cross-sectional view is shown with two build-up layers with a first build-up layer and a second build-up layer, although the integrated circuit packaging system 100 can include any number of the build-up layers. The first build-up layer is shown having the first inner conductive channel 126. The second build-up layer is shown having the second inner conductive channel 130, the first outer conductive channel 132, and the second outer conductive channel 134.

As an example, the integrated circuit packaging system 100 includes only the first build-up layer. In this example, the first inner conductive channel 126 is connected to the integrated circuit 108. Also in this example, the first outer conductive channel 132 is adjacent to the first inner conductive channel 126 and connected to the carrier 102 and the first outer interconnect 138. Further in this example, the second outer conductive channel 134 is connected to the carrier 102, the integrated circuit 108, and the second outer interconnect 142.

It has been discovered that the carrier 102, the first inner conductive channel 126, the first outer conductive channel 132, the second outer conductive channel 134, the first outer interconnect 138, the second outer interconnect 142, or a combination thereof provides a compact solution for EMI shielding. With the first outer conductive channel 132 connected to the first outer interconnect 138 that is externally connected to ground, the first outer conductive channel 132 connected to the carrier 102 provides a grounding path for the carrier 102 that functions as an EMI shield. With the second outer conductive channel 134 connected to the second outer interconnect 142 that is externally connected to ground, the second outer conductive channel 134 connected to the carrier 102 provides another grounding path for the carrier 102. The carrier 102 and the grounding path provide the compact solution for the EMI shielding.

It has also been discovered that the carrier 102, the attach layer 114, the first inner conductive channel 126, the first outer conductive channel 132, the second outer conductive channel 134, the first outer interconnect 138, the second outer interconnect 142, or a combination thereof provides thermal enhancement. With the first outer conductive channel 132 connected to the carrier 102 and the first outer interconnect 138 that is externally connected to ground, the attach layer 114 attached to the carrier 102 and the integrated circuit 108 conducts heat away from the integrated circuit 108. With the second outer conductive channel 134 connected to the carrier 102 and the second outer interconnect 142 that is externally connected to ground, heat is also conducted away from the integrated circuit 108. With the first inner conductive channel 126 connected to the second outer conductive channel 134 and the integrated circuit 108, heat is further conducted away from the integrated circuit 108. The thermal enhancement is provided with the heat conducted away from the integrated circuit 108.

It has further been discovered that the carrier 102, the encapsulation 122, or a combination thereof improves reliability for the integrated circuit packaging system 100. The reliability improvement also applies to wafer level chip scale package (WLCSP) packages that are somewhat worst than other package types. The reliability is improved by the integrated circuit 108 being mounted on the carrier 102. The reliability is also improved by the encapsulation 122 covering the integrated circuit 108.

Referring now to FIG. 2, therein is shown a top view of the integrated circuit packaging system 100. The integrated circuit packaging system 100 can include the inner interconnect 136 formed over or on the insulation layer 128. The inner interconnect 136 can be formed adjacent to or between the first outer interconnect 138 and the second outer interconnect 142.

For illustrative purposes, the first outer interconnect 138 and the second outer interconnect 142 are shown adjacent to the first external non-horizontal side 140 and the second external non-horizontal side 144, respectively, although the first outer interconnect 138 and the second outer interconnect 142 can be adjacent to any side along the periphery of the insulation layer 128. The integrated circuit packaging system 100 can include any number of the first outer interconnect 138 and the second outer interconnect 142 formed in an area array along the periphery of the insulation layer 128.

The integrated circuit packaging system 100 can include a number of the inner interconnect 136 formed adjacent to the first outer interconnect 138 or the second outer interconnect 142. The inner interconnect 136 can be formed in an array configuration bounded by the first outer interconnect 138 and the second outer interconnect 142 at the periphery of the integrated circuit packaging system 100.

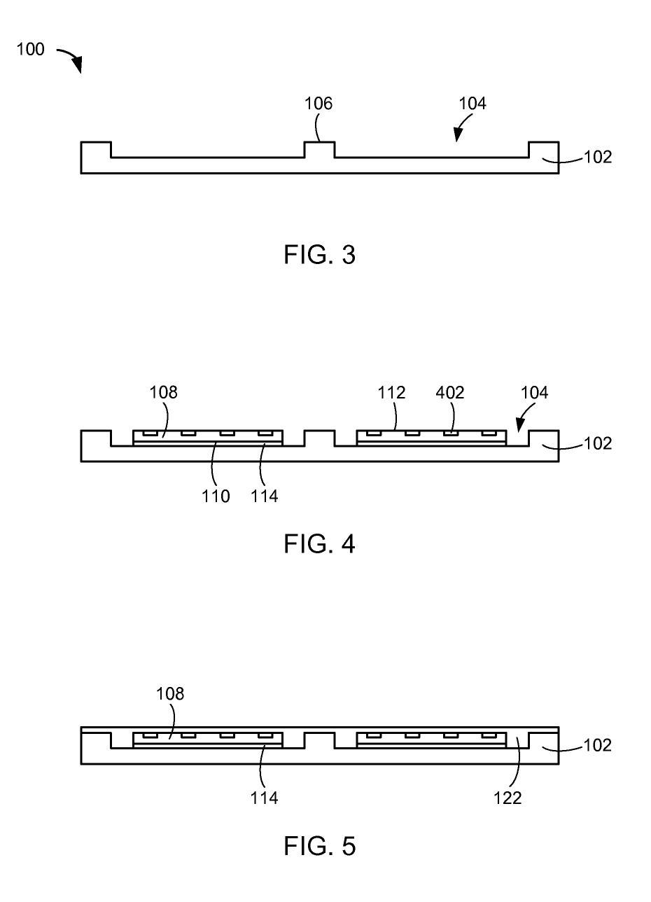

Referring now to FIG. 3, therein is shown a cross-sectional view of a portion of the integrated circuit packaging system 100 along the section line 1-1 of FIG. 2 in a forming phase of the carrier 102. The carrier 102 can be provided with a format, a form, or a structure of a wafer, a plate, a panel, a strip, or a conductive material.

The carrier 102 can include a metallic element, an alloy, or a thermally conductive material. The carrier 102 can be formed with the cavity 104 surrounded by the carrier top side 106.

Referring now to FIG. 4, therein is shown a cross-sectional view of the structure of FIG. 3 in a mounting phase of the integrated circuit 108. The integrated circuit 108 can include the inactive side 110 and the active side 112 opposite or over the inactive side 110. The integrated circuit 108 can be mounted in the cavity 104.

The integrated circuit 108 can be mounted with the inactive side 110 over the carrier 102. The integrated circuit 108 can be attached to the carrier 102 with the attach layer 114. The attach layer 114 can preferably include a type of conductive material for efficient heat dissipation.

The integrated circuit 108 can include a die pad 402, such as a contact, a lead, or a terminal. The die pad 402 can be formed with aluminum (Al), copper (Cu), Palladium (Pd), gold (Au), a metallic material, an alloy, or a conductor. The die pad 402 can have a predetermined thickness requirement to avoid or prevent silicon from being exposed by laser ablation or other removal methods.

Referring now to FIG. 5, therein is shown a cross-sectional view of the structure of FIG. 4 in a molding phase of the encapsulation 122. The encapsulation 122 can be formed over or on the carrier 102 covering the attach layer 114, or the integrated circuit 108. The encapsulation 122 can be formed by transfer molding, compression molding, spin coating, or any other molding methods.

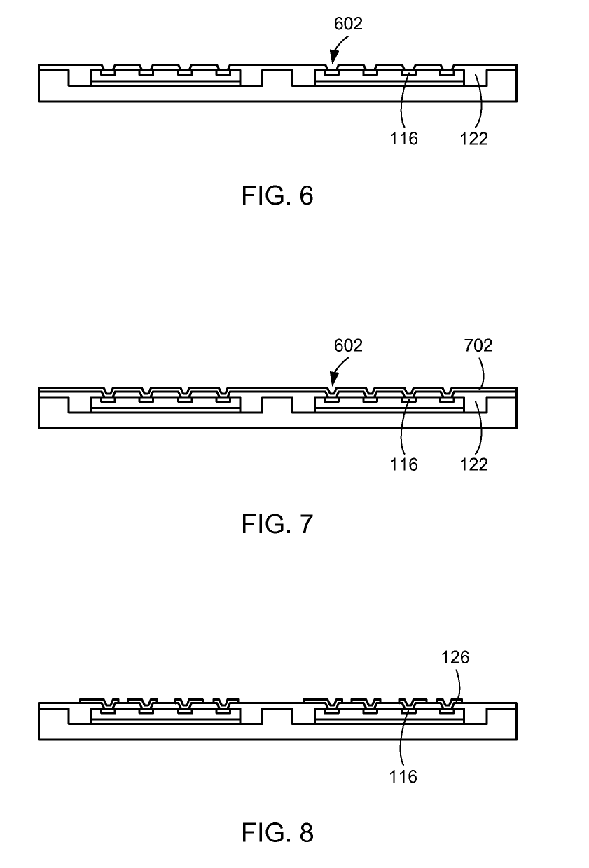

Referring now to FIG. 6, therein is shown a cross-sectional view of the structure of FIG. 5 in a forming phase of a first via 602. The first via 602 can be a hole or an aperture that can be formed through or in the encapsulation 122.

The first via 602 can expose a portion of the die pad 402 of FIG. 4 to form the bond pad 116. The first via 602 can be formed by chemical etching, photo-resist, direct laser ablation, drilling, or any other removal methods.

The bond pad 116 can include characteristics of the first via 602 formed exposing the die pad 402. The characteristics of the first via 602 formed can include physical features, such as a shallow cavity, a chemically processed surface, a recess or a micro recess, an etching residue, a chemical etching mark, an etched surface, chemical residue, marks due to laser ablation, or other removal tool marks. The bond pad 116 and the die pad 402 can be different due to the bond pad 116 having the characteristics of the first via 602 formed.

Referring now to FIG. 7, therein is shown a cross-sectional view of the structure of FIG. 6 in a forming phase of a first conductive layer 702. The first conductive layer 702 can be formed with a metallic material, an alloy, or a conductive material.

The first conductive layer 702 can be formed over or on the encapsulation 122. The first conductive layer 702 can be formed in the first via 602 over or on the bond pad 116. The first conductive layer 702 can be formed by electroless plating, sputtering seed plating, electro-plating, or any other deposition techniques.

Referring now to FIG. 8, therein is shown a cross-sectional view of the structure of FIG. 7 in a forming phase of the first inner conductive channel 126. The first inner conductive channel 126 can be connected to the bond pad 116.

The first inner conductive channel 126 can be formed by patterning the first conductive layer 702 of FIG. 7. The first inner conductive channel 126 can be formed by resist mask, chemical etching, photo-resist, direct laser ablation, or any other etching or removal process.

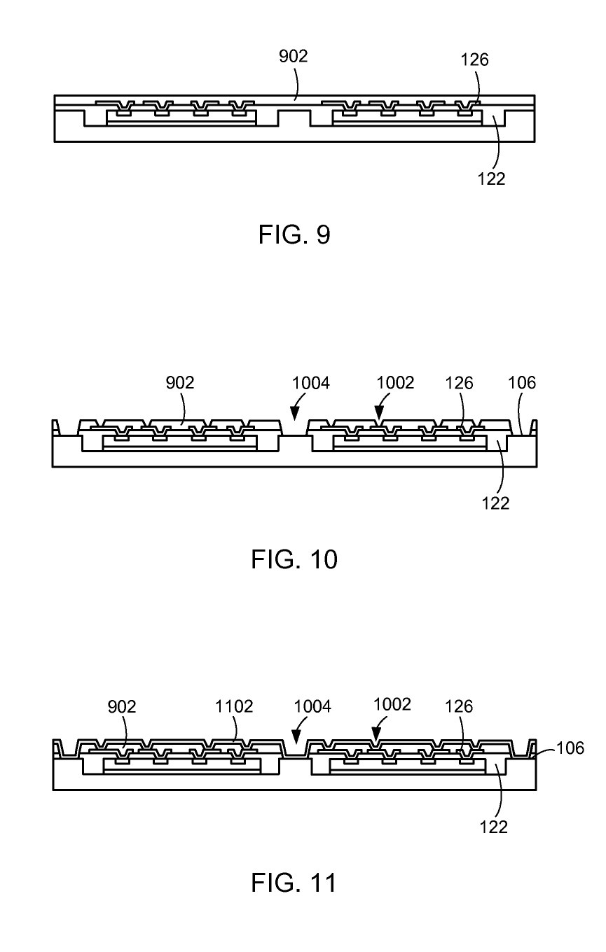

Referring now to FIG. 9, therein is shown a cross-sectional view of the structure of FIG. 8 in a forming phase of a first insulation layer 902. The first insulation layer 902 can be formed with a dielectric, an epoxy, a glass, a resin, an organic or inorganic material, a plastic or ceramic material, or a thermoplastic material.

The first insulation layer 902 can be formed over or on the encapsulation 122 or the first inner conductive channel 126. The first insulation layer 902 can be formed by spin coating, spray coating, needle dispensing, film lamination, screen printing, roll coating, or any other applications or deposition techniques.

Referring now to FIG. 10, therein is shown a cross-sectional view of the structure of FIG. 9 in a forming phase of a second via 1002 and a peripheral via 1004. The second via 1002 can include a hole or an aperture that can be formed through or in the first insulation layer 902. The peripheral via 1004 can include a hole or an aperture that can be formed through or in the encapsulation 122 and the first insulation layer 902.

The second via 1002 can be formed over the first inner conductive channel 126 and, expose a portion of the first inner conductive channel 126. The second via 1002 can be formed by chemical etching, photo-resist, direct laser ablation, drilling, or any other removal methods.

The peripheral via 1004 can be formed over the carrier top side 106 and expose a portion of the carrier top side 106. The peripheral via 1004 can be formed by etching, photo-resist, laser ablation, drilling, or any other removal methods.

Referring now to FIG. 11, therein is shown a cross-sectional view of the structure of FIG. 10 in a forming phase of a second conductive layer 1102. The second conductive layer 1102 can be formed with a metallic material, an alloy, or a conductive material.

The second conductive layer 1102 can be formed over or on the encapsulation 122, the first insulation layer 902, or a combination thereof. The second conductive layer 1102 can be formed in the second via 1002. The second conductive layer 1102 can be over or on the first inner conductive channel 126.

The second conductive layer 1102 can be formed in the peripheral via 1004. The second conductive layer 1102 can be over or on the carrier top side 106. The second conductive layer 1102 can be formed by electroless plating, sputtering seed plating, electro-plating, or any other deposition techniques.

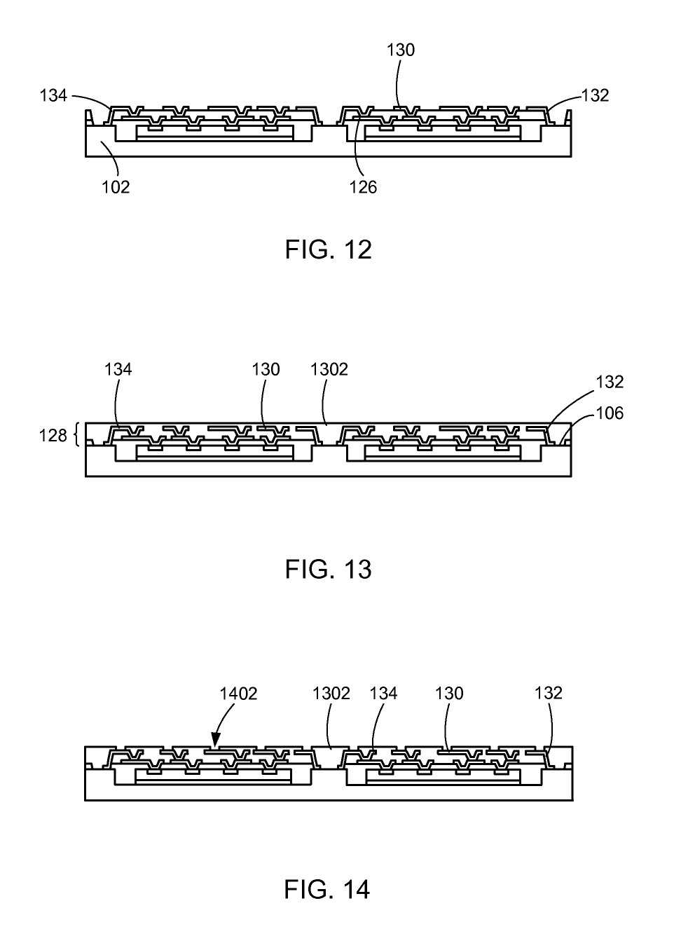

Referring now to FIG. 12, therein is shown a cross-sectional view of the structure of FIG. 11 in a forming phase of the second inner conductive channel 130, the first outer conductive channel 132, and the second outer conductive channel 134. The second inner conductive channel 130 can be connected to the first inner conductive channel 126.

The first outer conductive channel 132 can be adjacent to the second inner conductive channel 130. The first outer conductive channel 132 can be connected to the carrier 102.

The second outer conductive channel 134 can be adjacent to the second inner conductive channel 130. The second outer conductive channel 134 can be connected to the carrier 102 or another of the first inner conductive channel 126. The first outer conductive channel 132 or the second outer conductive channel 134 can be connected to the carrier 102 to provide an EMI shield connection.

The second inner conductive channel 130, the first outer conductive channel 132, or the second outer conductive channel 134 can be formed by patterning the second conductive layer 1102 of FIG. 11. The second inner conductive channel 130, the first outer conductive channel 132, or the second outer conductive channel 134 can be formed resist mask, chemical etching, photo-resist, direct laser ablation, or any other etching or removal process.

Referring now to FIG. 13, therein is shown a cross-sectional view of the structure of FIG. 12 in a forming phase of a second insulation layer 1302. The second insulation layer 1302 can be formed with a dielectric, an epoxy, a glass, a resin, an organic or inorganic material, a plastic or ceramic material, or a thermoplastic material.

The second insulation layer 1302 can be formed over or on the carrier top side 106, the second inner conductive channel 130, the first outer conductive channel 132, the second outer conductive channel 134, or the first insulation layer 902 of FIG. 9. The second insulation layer 1302 can be formed by spin coating, spray coating, needle dispensing, film lamination, screen printing, roll coating, or any other applications or deposition techniques. The cross-sectional view is shown with the second insulation layer 1302 as the top-most insulation layer.

For illustrative purposes, the insulation layer 128 of FIG. 1 is shown as a single integral structure, although the insulation layer 128 can be formed with a number of the insulation layers that can be formed over or on one another. For example, the insulation layer 128 can include the first insulation layer 902 and the second insulation layer 1302 formed thereon.

Referring now to FIG. 14, therein is shown a cross-sectional view of the structure of FIG. 13 in a forming phase of an opening 1402. The opening 1402 can be a ball pad opening, a hole, or an aperture that can be formed through or in the second insulation layer 1302.

The opening 1402 can be formed over the second inner conductive channel 130, the first outer conductive channel 132, or the second outer conductive channel 134. The opening 1402 can partially expose the second inner conductive channel 130, the first outer conductive channel 132, or the second outer conductive channel 134. The opening 1402 can be formed by chemical etching, photo-resist, direct laser ablation, drilling, or any other removal method.

A contact (not shown), such as a ball pad or a contact pad, can be optionally formed over, on, or in the opening 1402. The contact can be electrically connected to the second inner conductive channel 130, the first outer conductive channel 132, or the second outer conductive channel 134.

The contact can be formed by filling or depositing the opening 1402 with a metal layer, a conductive layer, or an under bump metallization (UBM). For example, the contact can be formed by evaporation, electrolytic plating, electroless plating, screen printing process, or any other deposition processes.

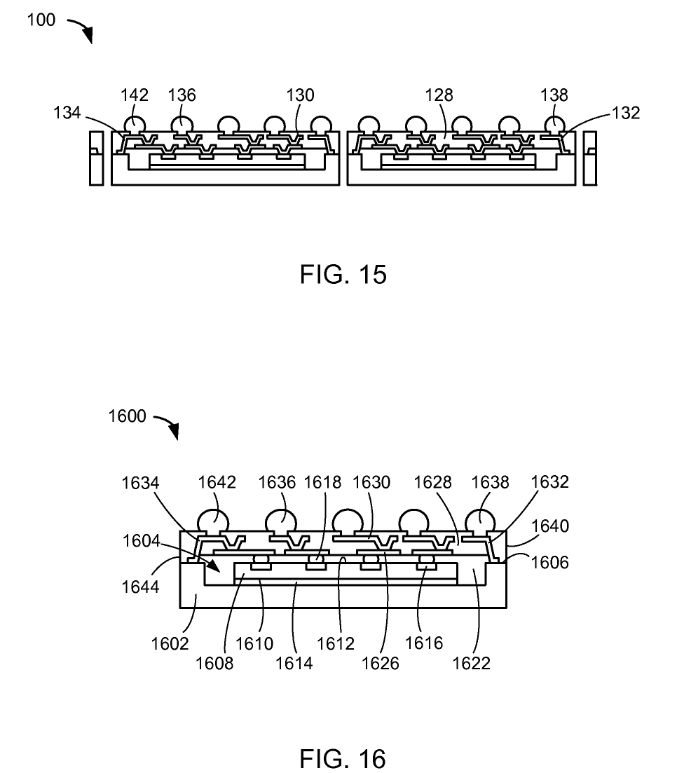

Referring now to FIG. 15, therein is shown a cross-sectional view of the structure of FIG. 14 in a singulation phase of the integrated circuit packaging system 100. The inner interconnect 136, the first outer interconnect 138, or the second outer interconnect 142 can be formed or mounted over or on the insulation layer 128 with a solder ball mount (SBM) process or any other mount processes.

The inner interconnect 136, the first outer interconnect 138, or the second outer interconnect 142 can be attached or connected to the second inner conductive channel 130, the first outer conductive channel 132, or the second outer conductive channel 134, respectively. If the contact is optionally formed as described in FIG. 14, the inner interconnect 136, the first outer interconnect 138, or the second outer interconnect 142 can be formed over or on the contact to electrically connect to the second inner conductive channel 130, the first outer conductive channel 132, or the second outer conductive channel 134, respectively.

The inner interconnect 136, the first outer interconnect 138, or the second outer interconnect 142 can be formed over the opening 1402 of FIG. 14. A singulation process can be used to form or separate the integrated circuit packaging system 100 into individual units as a final product.

Referring now to FIG. 16, therein is shown a cross-sectional view as exemplified by the top view of FIG. 2 of an integrated circuit packaging system 1600 in a second embodiment of the present invention. The integrated circuit packaging system 1600 can be similar to the integrated circuit packaging system 100 of FIG. 1, except for the formation of the integrated circuit 108 of FIG. 1, the encapsulation 122 of FIG. 1, or the first inner conductive channel 126 of FIG. 1.

The integrated circuit packaging system 1600 can include a carrier 1602 having a cavity 1604 and a carrier top side 1606. The carrier 1602 can be formed in a manner similar to the carrier 102 of FIG. 1.

The integrated circuit packaging system 1600 can include an integrated circuit 1608, such as a bumped chip, a flip chip, or a semiconductor device. The integrated circuit 1608 can include an inactive side 1610 and an active side 1612 opposite or over the inactive side 1610. The integrated circuit 1608 can be placed or mounted in the cavity 1604 or over the carrier 1602.

The integrated circuit packaging system 1600 can include an attach layer 1614. The attach layer 1614 can be formed in a manner similar to the attach layer 114 of FIG. 1. The inactive side 1610 can be attached to the carrier 1602 with the attach layer 1614.

The integrated circuit 1608 can include a bond pad 1616, such as a contact, a lead, or a terminal. The bond pad 1616 can be formed on the active side 1612.

The integrated circuit 1608 can include an internal interconnect 1618, such as a bump, a ball, a post, a pillar, or a connector. For example, the internal interconnect 1618 can be formed with solder, a metallic material, an alloy, or a conductive material. The internal interconnect 1618 can be attached or connected to the bond pad 1616.

The integrated circuit packaging system 1600 can include an encapsulation 1622, such as a cover including an encapsulant, an epoxy molding compound, or a molding material. The encapsulation 1622 can be formed over or on the carrier 1602, the attach layer 1614, or the integrated circuit 1608.

The encapsulation 1622 can be formed over or on the internal interconnect 1618, exposing a portion of the internal interconnect 1618. The encapsulation 1622 can be formed over or in the cavity 1604. The encapsulation 1622 can be partially formed over or on the carrier top side 1606.

The integrated circuit packaging system 1600 can include a first inner conductive channel 1626, such as a patterned routing layer, a redistribution layer (RDL), a build-up layer, a trace, or a wire, formed over or on the encapsulation 1622 or the portion of the internal interconnect 1618 that is exposed from the encapsulation 1622. The first inner conductive channel 1626 can conduct or carry electrical signals. The first inner conductive channel 1626 can be electrically connected to the internal interconnect 1618.

The integrated circuit packaging system 1600 can include a second inner conductive channel 1630, a first outer conductive channel 1632, and a second outer conductive channel 1634. The second inner conductive channel 1630, the first outer conductive channel 1632, and the second outer conductive channel 1634 can be formed in a manner similar to the second inner conductive channel 130 of FIG. 1, the first outer conductive channel 132 of FIG. 1, and the second outer conductive channel 134 of FIG. 1, respectively.

The integrated circuit packaging system 1600 can include an insulation layer 1628 having a first external non-horizontal side 1640 and a second external non-horizontal side 1644. The integrated circuit packaging system 1600 can include an inner interconnect 1636, a first outer interconnect 1638, and a second outer interconnect 1642. The insulation layer 1628, the inner interconnect 1636, the first outer interconnect 1638, and the second outer interconnect 1642 can be formed in a manner similar to the insulation layer 128 of FIG. 1, the inner interconnect 136 of FIG. 1, the first outer interconnect 138 of FIG. 1, and the second outer interconnect 142 of FIG. 1, respectively.

It has been discovered that the carrier 1602, the attach layer 1614, the first inner conductive channel 1626, the first outer conductive channel 1632, the second outer conductive channel 1634, the first outer interconnect 1638, the second outer interconnect 1642, or a combination thereof provides thermal enhancement. With the first outer conductive channel 1632 connected to the carrier 1602 and the first outer interconnect 1638 that is externally connected to ground, the attach layer 1614 attached to the carrier 1602 and the integrated circuit 1608 conducts heat away from the integrated circuit 1608. With the second outer conductive channel 1634 connected to the carrier 1602 and the second outer interconnect 1642 that is externally connected to ground, heat is also conducted away from the integrated circuit 1608. With the first inner conductive channel 1626 connected to the second outer conductive channel 1634 and the internal interconnect 1618, heat is further conducted away from the integrated circuit 1608. The thermal enhancement is provided with the heat conducted away from the integrated circuit 1608.

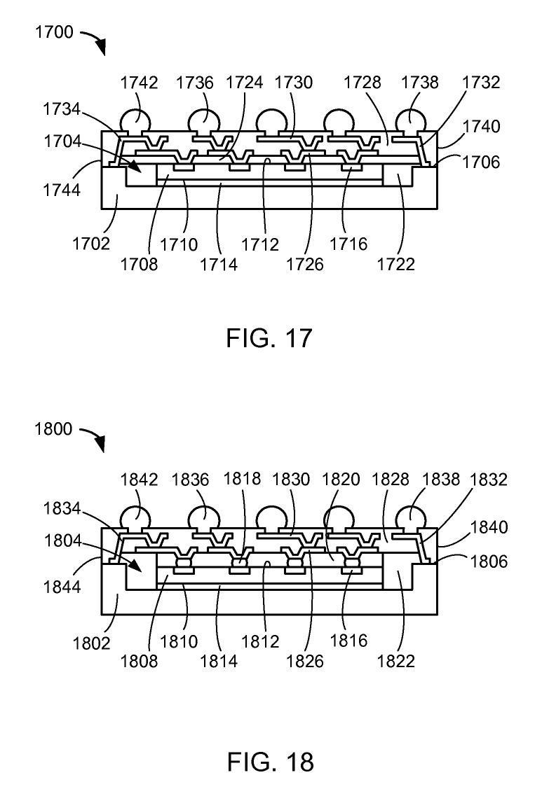

Referring now to FIG. 17, therein is shown a cross-sectional view as exemplified by the top view of FIG. 2 of an integrated circuit packaging system 1700 in a third embodiment of the present invention. The integrated circuit packaging system 1700 can be similar to the integrated circuit packaging system 100 of FIG. 1, except for an addition of a protection layer and the formation of the encapsulation 122 of FIG. 1, the first inner conductive channel 126 of FIG. 1, the first outer conductive channel 132 of FIG. 1, the second outer conductive channel 134 of FIG. 1, and the insulation layer 128 of FIG. 1.

The integrated circuit packaging system 1700 can include a carrier 1702 having a cavity 1704 and a carrier top side 1706. The integrated circuit packaging system 1700 can include an integrated circuit 1708 having an inactive side 1710 and an active side 1712. The integrated circuit packaging system 1700 can include an attach layer 1714.

The carrier 1702 and the attach layer 1714 can be formed in a manner similar to the carrier 102 of FIG. 1 and the attach layer 114 of FIG. 1, respectively. The integrated circuit 1708 having a bond pad 1716 can be formed in a manner similar to the integrated circuit 108 of FIG. 1.

The integrated circuit packaging system 1700 can include an encapsulation 1722, such as a cover including an encapsulant, an epoxy molding compound, or a molding material. The encapsulation 1722 can be partially formed over or on the carrier 1702 or the attach layer 1714.

The encapsulation 1722 can be formed over or in the cavity 1704. The encapsulation 1722 can be partially formed over or on the carrier top side 1706.

The integrated circuit packaging system 1700 can include a buffer layer 1724, such as a transparent material, rubber, silicon, a dielectric, a polymer, an insulation material, a film, or a film assist mold (FAM). The encapsulation 1722 can be formed on a portion of the buffer layer 1724 or partially between the carrier top side 1706 and the buffer layer 1724.

The buffer layer 1724 can be formed, attached, or deposited over or on the active side 1712 such that the encapsulation 1722 can be formed on a portion of the integrated circuit 1708. The buffer layer 1724 can function as the protection layer to avoid or prevent the encapsulation 1722 from being molded or formed over or on the active side 1712. The encapsulation 1722 can be formed with a film assist mold (FAM) process, a plain molding process, or any other encapsulation processes.

The integrated circuit packaging system 1700 can include a first inner conductive channel 1726, such as a patterned routing layer, a redistribution layer (RDL), a build-up layer, a trace, or a wire, formed over or on the buffer layer 1724. The buffer layer 1724 can be between the active side 1712 and the first inner conductive channel 1726.

The first inner conductive channel 1726 can be formed over or on a portion of the bond pad 1716 that is exposed from the buffer layer 1724. The first inner conductive channel 1726 can conduct or carry electrical signals. The first inner conductive channel 1726 can be formed through the buffer layer 1724 and electrically connected to the bond pad 1716.

The integrated circuit packaging system 1700 can include a second inner conductive channel 1730. The second inner conductive channel 1730 can be formed in a manner similar to the second inner conductive channel 130 of FIG. 1.

The integrated circuit packaging system 1700 can include a first outer conductive channel 1732, such as a patterned routing layer, a redistribution layer (RDL), a build-up layer, a trace, or a wire, partially formed over or on the carrier 1702, the encapsulation 1722, or the buffer layer 1724. The first outer conductive channel 1732 can be adjacent to the second inner conductive channel 1730.

The first outer conductive channel 1732 can conduct or carry electrical signals. The first outer conductive channel 1732 can be electrically connected to the carrier top side 1706.

The integrated circuit packaging system 1700 can include a second outer conductive channel 1734, such as a patterned routing layer, a redistribution layer (RDL), a build-up layer, a trace, or a wire. The second outer conductive channel 1734 can be partially formed over or on the carrier 1702, the encapsulation 1722, the buffer layer 1724, or another of the first inner conductive channel 1726. The second outer conductive channel 1734 can be adjacent to another of the second inner conductive channel 1730.

The second outer conductive channel 1734 can conduct or carry electrical signals. The second outer conductive channel 1734 can be electrically connected to the carrier top side 1706 or the another of the first inner conductive channel 1726.

The integrated circuit packaging system 1700 can include an insulation layer 1728, such as a dielectric, an epoxy, a glass, a resin, an organic or inorganic material, a plastic or ceramic material, or a thermoplastic material. The insulation layer 1728 can be partially formed over or on the carrier 1702, the encapsulation 1722, the buffer layer 1724, the first inner conductive channel 1726, the second inner conductive channel 1730, the first outer conductive channel 1732, or the second outer conductive channel 1734.

The integrated circuit packaging system 1700 can include an inner interconnect 1736 and a first outer interconnect 1738. The inner interconnect 1736 and the first outer interconnect 1738 can be formed in a manner similar to the inner interconnect 136 of FIG. 1 and the first outer interconnect 138 of FIG. 1, respectively.

The first outer interconnect 1738 can be formed adjacent to or near a first external non-horizontal side 1740 of the insulation layer 1728. The first external non-horizontal side 1740 can be formed in a manner similar to the first external non-horizontal side 140 of FIG. 1.

The integrated circuit packaging system 1700 can include a second outer interconnect 1742. The second outer interconnect 1742 can be formed in a manner similar to the second outer interconnect 142 of FIG. 1.

The second outer interconnect 1742 can be formed adjacent to or near a second external non-horizontal side 1744 of the insulation layer 1728. The second external non-horizontal side 1744 can be formed in a manner similar to the second external non-horizontal side 144 of FIG. 1.

It has been discovered that the buffer layer 1724 avoids molding of the encapsulation 1722 on the active side 1712 so that redistribution of the first inner conductive channel 1726 can be formed readily thereby increasing yield and reliability through proven manufacturing processes.

It has also been discovered that the buffer layer 1724 provides further fine alignment of the first inner conductive channel 1726. With the buffer layer 1724 being transparent, the first inner conductive channel 1726 is readily formed on the bond pad 1716 thereby providing the further fine alignment.

Referring now to FIG. 18, therein is shown a cross-sectional view as exemplified by the top view of FIG. 2 of an integrated circuit packaging system 1800 in a fourth embodiment of the present invention. The integrated circuit packaging system 1800 can be similar to the integrated circuit packaging system 100 of FIG. 1, except for the formation of the integrated circuit 108 of FIG. 1, the encapsulation 122 of FIG. 1, the first inner conductive channel 126 of FIG. 1, and the insulation layer 128 of FIG. 1.

The integrated circuit packaging system 1800 can include a carrier 1802 having a cavity 1804 and a carrier top side 1806. The carrier 1802 can be formed in a manner similar to the carrier 102 of FIG. 1.

The integrated circuit packaging system 1800 can include an integrated circuit 1808, such as a pre-molded bumped chip, a pre-molded flip chip, or a semiconductor device. The integrated circuit 1808 can include an inactive side 1810 and an active side 1812 opposite or over the inactive side 1810. The integrated circuit 1808 can be placed or mounted in the cavity 1804 or over the carrier 1802.

The inactive side 1810 can be attached to the carrier 1802 with an attach layer 1814. The attach layer 1814 can be formed in a manner similar to the attach layer 114 of FIG. 1.

The integrated circuit 1808 can include a bond pad 1816, such as a contact, a lead, or a terminal. The bond pad 1816 can be formed on the active side 1812.

The integrated circuit 1808 can include an internal interconnect 1818, such as a bump, a ball, a post, a pillar, or a connector. For example, the internal interconnect 1818 can be formed with solder, a metallic material, an alloy, or a conductive material. The internal interconnect 1818 can be formed or mounted over or on, attached to, or connected to the bond pad 1816.

The integrated circuit 1808 can include a protection liner 1820, such as a cover including an encapsulant, an epoxy molding compound, a polyimide, or a molding material. The protection liner 1820 can be formed over or on the active side 1812 or the internal interconnect 1818.

The protection liner 1820 can be pre-molded or formed over the integrated circuit 1808 prior to the integrated circuit 1808 being mounted over the carrier 1802. For example, the protection liner 1820 can be formed with wafer level encapsulation, mold chase, spin coating, pre-applied film lamination, or any other encapsulation methods.

The integrated circuit packaging system 1800 can include an encapsulation 1822, such as a cover including an encapsulant, an epoxy molding compound, or a molding material. The encapsulation 1822 can be partially formed over or on the carrier 1802 or the attach layer 1814. The protection liner 1820 can be surrounded by the encapsulation 1822.

The encapsulation 1822 can be formed over or in the cavity 1804. The encapsulation 1822 can be partially formed over or on the carrier top side 1806 or the protection liner 1820.

The integrated circuit packaging system 1800 can include a first inner conductive channel 1826, such as a patterned routing layer, a redistribution layer (RDL), a build-up layer, a trace, or a wire, formed over or on the internal interconnect 1818, the protection liner 1820, or the encapsulation 1822. The protection liner 1820 can be between the active side 1812 and the first inner conductive channel 1826.

The first inner conductive channel 1826 can be formed over or on a portion of the internal interconnect 1818 that is exposed from the protection liner 1820. The first inner conductive channel 1826 can conduct or carry electrical signals. The first inner conductive channel 1826 can be formed through the protection liner 1820 and electrically connected to the internal interconnect 1818.

The integrated circuit packaging system 1800 can include a second inner conductive channel 1830, a first outer conductive channel 1832, and a second outer conductive channel 1834. The second inner conductive channel 1830, the first outer conductive channel 1832, and the second outer conductive channel 1834 can be formed in a manner similar to the second inner conductive channel 130 of FIG. 1, the first outer conductive channel 132 of FIG. 1, and the second outer conductive channel 134 of FIG. 1.

The integrated circuit packaging system 1800 can include an insulation layer 1828, such as a dielectric, an epoxy, a glass, a resin, an organic or inorganic material, a plastic or ceramic material, or a thermoplastic material. The insulation layer 1828 can be formed over or on the carrier 1802, the encapsulation 1822, the protection liner 1820, the first inner conductive channel 1826, the second inner conductive channel 1830, the first outer conductive channel 1832, or the second outer conductive channel 1834.

The integrated circuit packaging system 1800 can include an inner interconnect 1836 and a first outer interconnect 1838. The inner interconnect 1836 and the first outer interconnect 1838 can be formed in a manner similar to the inner interconnect 136 of FIG. 1 and the first outer interconnect 138 of FIG. 1, respectively.

The first outer interconnect 1838 can be formed adjacent to or near a first external non-horizontal side 1840 of the insulation layer 1828. The first external non-horizontal side 1840 can be formed in a manner similar to the first external non-horizontal side 140 of FIG. 1.

The integrated circuit packaging system 1800 can include a second outer interconnect 1842. The second outer interconnect 1842 can be formed in a manner similar to the second outer interconnect 142 of FIG. 1.

The second outer interconnect 1842 can be formed adjacent to or near a second external non-horizontal side 1844 of the insulation layer 1828. The second external non-horizontal side 1844 can be formed in a manner similar to the second external non-horizontal side 144 of FIG. 1.

It has been discovered that the integrated circuit 1808 having the protection liner 1820 provides further stress release. The protection liner 1820 protects the internal interconnect 1818 and the active side 1812 from thermal or mechanical stress that can cause cracks or damages to the integrated circuit 1808 during subsequent manufacturing processes, resulting in further stress release.

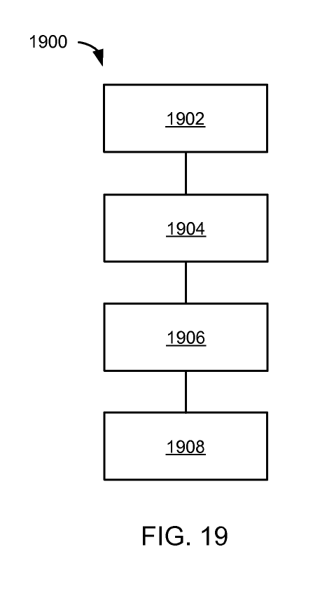

Referring now to FIG. 19, therein is shown a flow chart of a method 1900 of manufacture of an integrated circuit packaging system in a further embodiment of the present invention. The method 1900 includes: forming a carrier having a cavity and a carrier top side adjacent to the cavity in a block 1902; mounting an integrated circuit in the cavity in a block 1904; forming an encapsulation surrounding the integrated circuit in a block 1906; and attaching a conductive channel to the carrier top side, the conductive channel over the encapsulation in a block 1908.

The resulting method, process, apparatus, device, product, and/or system is straightforward, cost-effective, uncomplicated, highly versatile, accurate, sensitive, and effective, and can be implemented by adapting known components for ready, efficient, and economical manufacturing, application, and utilization.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
forming a carrier having a cavity and a carrier top side adjacent to the cavity;
mounting an integrated circuit in the cavity;
forming an encapsulation surrounding the integrated circuit; and
attaching a conductive channel to the carrier top side, the conductive channel over the encapsulation.

2. The method as claimed in claim 1 wherein forming the encapsulation includes forming the encapsulation partially on the carrier and over the integrated circuit.

3. The method as claimed in claim 1 further comprising grounding the conductive channel to form an electromagnetic interference shield.

4. The method as claimed in claim 1 further comprising attaching a buffer layer on the integrated circuit.

5. The method as claimed in claim 1 wherein:
mounting the integrated circuit includes mounting the integrated circuit having a protection liner; and
forming the encapsulation surrounding the integrated circuit includes forming the encapsulation surrounding the protection liner.

6. A method of manufacture of an integrated circuit packaging system comprising:
forming a carrier having a cavity and a carrier top side adjacent to the cavity;
mounting an integrated circuit in the cavity;
forming an encapsulation surrounding the integrated circuit;
attaching a conductive channel to the carrier top side, the conductive channel over the encapsulation;
forming an insulation layer over the encapsulation and the conductive channel, the insulation layer having an opening; and
connecting an interconnect to the conductive channel, the interconnect over the opening.

7. The method as claimed in claim 6 further comprising:
attaching a buffer layer on the integrated circuit; and
connecting the conductive channel to the integrated circuit through the buffer layer.

8. The method as claimed in claim 6 wherein:
mounting the integrated circuit includes mounting the integrated circuit having a protection liner; and
further comprising:
connecting the conductive channel to the integrated circuit through the protection liner.

9. The method as claimed in claim 6 wherein mounting the integrated circuit includes attaching an attach layer to the carrier and the integrated circuit over the carrier.

10. The method as claimed in claim 6 wherein mounting the integrated circuit includes mounting a bumped chip in the cavity.

11. An integrated circuit packaging system comprising:
a carrier having a cavity and a carrier top side adjacent to the cavity;
an integrated circuit in the cavity;
an encapsulation surrounding the integrated circuit; and
a conductive channel attached to the carrier top side, the conductive channel over the encapsulation.

12. The system as claimed in claim 11 wherein the encapsulation includes the encapsulation partially on the carrier and over the integrated circuit.

13. The system as claimed in claim 11 wherein the conductive channel is grounded to form an electromagnetic interference shield with the carrier.

14. The system as claimed in claim 11 further comprising a buffer layer on the integrated circuit.

15. The system as claimed in claim 11 wherein:
the integrated circuit includes the integrated circuit having a protection liner; and
the encapsulation surrounding the integrated circuit includes the encapsulation surrounding the protection liner.

16. The system as claimed in claim 11 further comprising:
an insulation layer over the encapsulation and the conductive channel, the insulation layer having an opening; and
an interconnect connected to the conductive channel, the interconnect over the opening.

17. The system as claimed in claim 16 further comprising:
a buffer layer on the integrated circuit; and
the conductive channel connected to the integrated circuit through the buffer layer.

18. The system as claimed in claim 16 wherein:
the integrated circuit includes the integrated circuit having a protection liner; and
the conductive channel includes the conductive channel connected to the integrated circuit through the protection liner.

19. The system as claimed in claim 16 further comprising an attach layer attached to the carrier and the integrated circuit over the carrier.

20. The system as claimed in claim 16 wherein the integrated circuit includes a bumped chip in the cavity.
